(19) United States
(12) Patent Application Publication
(10) Pub. No.: US 2008/0277779 A1
(43) Pub. Date: Nov. 13, 2008

(54) Microelectronic package and method of manufacturing same

(76) Inventors: Abhishek Gupta, Chandler, AZ (US); Zhiyong Wang, Chandler, AZ (US); Chuan Hu, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/800,686

(22) Filed: May 7, 2007

(51) Int. Cl. H01L 23/34; H01L 21/58; H01L 23/36

(52) U.S. Cl. 257/714; 257/712; 438/118; 257/E23.101; 257/E21.505

(57) ABSTRACT

A microelectronic package comprises a substrate (110), a die (120) having a front side (121) and a back side (122) located over the substrate, a thermally conducting layer (130) on the back side of the die, a microchannel (140) above the thermally conducting layer, and a cap (150) on the microchannel. The thermally conducting layer between the die and the microchannel may lend mechanical strength to the package, may be thin enough to be compliant and avoid contributing meaningful CTE mismatch with the die, and may prevent the formation or propagation of cracks in the microchannel.

### FIELD OF THE INVENTION

The disclosed embodiments of the invention relate generally to microelectronic packages, and relate more particularly to thermal management and mechanical stability in microelectronic packages.

### BACKGROUND OF THE INVENTION

Certain high-performance computer dies generate large amounts of heat that must be addressed by aggressive thermal management techniques in order to avoid damage to the die or its environment. One such thermal management technique involves the use of copper microchannels having fins that take heat from a die and transfer it to a cooling fluid circulating around the fins. Unfortunately, it is difficult to integrate copper with the silicon used in the die without a thermal interface material (TIM) that adds complexity and often great expense. Furthermore, the large mismatch in coefficient of thermal expansion (CTE) between copper and silicon often leads to problems like warpage and die cracking.

Some packages contain an integrated heat spreader (IHS) between the die and the microchannel, and these packages often experience reliability stress failures due to microcracks in and around the intermetallics formed between the IHS and the TIM. Variability in IHS quality also contributes to this problem. Chip-stack or 3D packages add another level of complexity that further complicates the thermal management problem.

Microchannels made of silicon rather than of copper have been proposed as a solution to at least some of the problems mentioned above. However, silicon microchannels may suffer from poor mechanical strength, which may also hinder the 3-D stacking of central processing units (CPUs), chipsets, and dynamic random access memory (DRAM). Mechanically weak microchannels (especially the edges) will be highly prone to crack initiation and propagation and will significantly affect the reliability of the active silicon and of the entire package. Accordingly, there exists a need for a microelectronic package that is both thermally and mechanically compatible with high-performance computer dies.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of a microelectronic package according to an embodiment of the invention; and

FIG. 2 is a flowchart illustrating a method of manufacturing a microelectronic package according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a microelectronic package comprises a substrate, a die having a front side and a back side located over the substrate, a thermally conducting layer on the back side of the die, a microchannel above the thermally conducting layer, and a cap on the microchannel. The thermally conducting layer between the die and the microchannel may lend mechanical strength to the package, may be thin enough to be compliant and avoid contributing meaningful CTE mismatch with the die, and may prevent the formation or propagation of cracks in the microchannel.

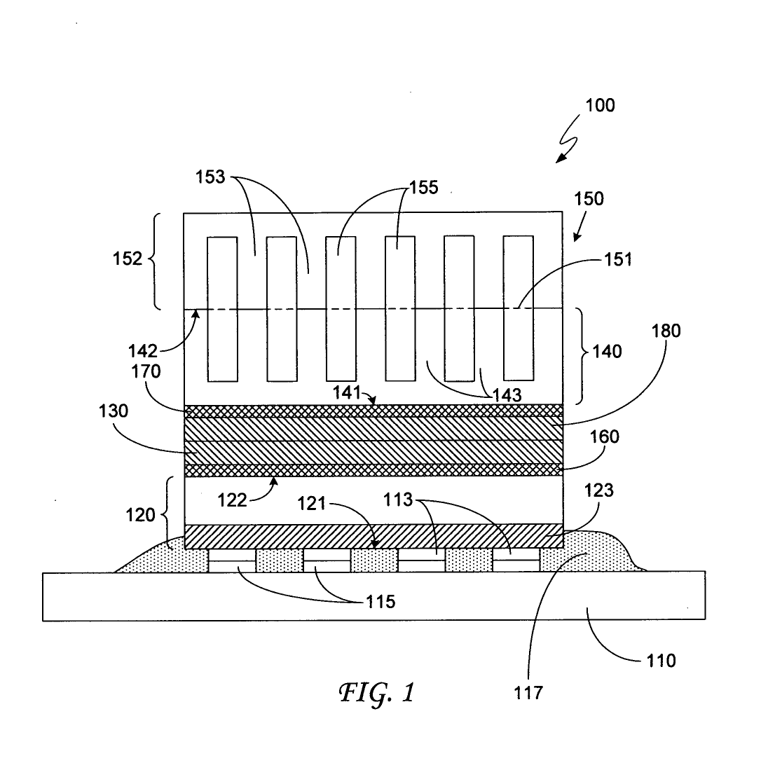

Referring now to the drawings, FIG. 1 is a cross-sectional view of a microelectronic package 100 according to an embodiment of the invention. As illustrated in FIG. 1, microelectronic package 100 comprises a substrate 110, a die 120 having a front side 121 and a back side 122 located over substrate 110, a thermally conducting layer 130 on back side 122 of die 120, a microchannel 140 with fins 143 above thermally conducting layer 130, and a cap 150 on microchannel 140. Die 120 has an active region 123 near front side 121.

In the illustrated embodiment, microelectronic package 100 further comprises a barrier layer 160 between back side 122 of die 120 and thermally conducting layer 130. Also in the illustrated embodiment, microchannel 140 has a surface 141 and a surface 142, with cap 150 at surface 142, and microchannel 140 further comprises a barrier layer 170 at surface 141 and a thermally conducting layer 180 over barrier layer 170 (meaning barrier layer 170 is between thermally conducting layer 180 and microchannel 140). As an example, thermally conducting layer 180 can be similar to thermally conducting layer 130, and barrier layer 170 can be similar to barrier layer 160. Microelectronic package 100 still further comprises pads 113, solder bumps 115, and an underfill material 117.

In one embodiment, die 120 and microchannel 140 are both made of (or comprise) silicon. In the same or another embodiment, one or both of thermally conducting layers 130 and 180 comprise copper, gold, nickel, silver, or another highly thermally conductive material. The copper or other thermally conductive material may act as a stiffener and as a bonding agent on back side 122 of die 120, regardless of whether die 120 is a thinned die or a die that has not been thinned. The stiffening effect of the thermally conducting layer may be similar to that provided by a core used in organic substrates. The copper or other thermally conductive material may also lend mechanical strength to microelectronic package 100, thus, for example, allowing 3-D stacking (along with through-silicon vias and/or wire bonding) or other processes requiring a robust package. Furthermore, using silicon instead of copper or another material may significantly reduce the cost of the microchannel.

The thermally conductive material may further act to eliminate the formation or arrest the propagation of cracks and other defects that may be caused due to the fabrication of microchannels within the silicon (or other material) of die 120, or during the stresses of reliability testing, and thus eliminate or reduce performance problems for die 120 that may occur if such cracks or other defects were allowed to extend into active region 123 of die 120.

In one embodiment, one or both of barrier layers 160 and 170 comprise tantalum, tantalum/nitride or another material or mix of materials capable of acting as a diffusion barrier between the silicon (or other material) of die 120 and microchannel 140 and the copper (or other material) of thermally conducting layers 130 and 180.

With both die 120 and microchannel 140 made of silicon, the CTE mismatch between die and microchannel becomes negligible. Intervening thermally conducting layer 130 will not add an appreciable CTE mismatch provided it is thin enough; accordingly, in one embodiment thermally conducting layer 130 is no thicker than approximately five micrometers, a thickness value that preserves the CTE advantages available when both die and microchannel are made of the same material as in the embodiment under discussion here.

Cap 150 acts as a cover over microchannel 140 in order to provide channels in which coolant can flow. In one embodiment, cap 150 is a substantially flat lid (represented in FIG. 1 by a dotted line 151) extending across surface 142 of microchannel 140. In another embodiment, cap 150 is a microchannel 152 with fins 153 that is flipped upside down with respect to microchannel 140 and placed on top of microchannel 140. In either embodiment, cap 150 creates channels 155 in which coolant can flow for the purpose of removing heat from die 120. It should be understood that the sequences of the intergeneration described above can be changed from wafer level to single die level (or vice versa) to provide ease of processing. As an example, wafer level integration may be performed prior to a pick and place operation even after singulation has occurred.

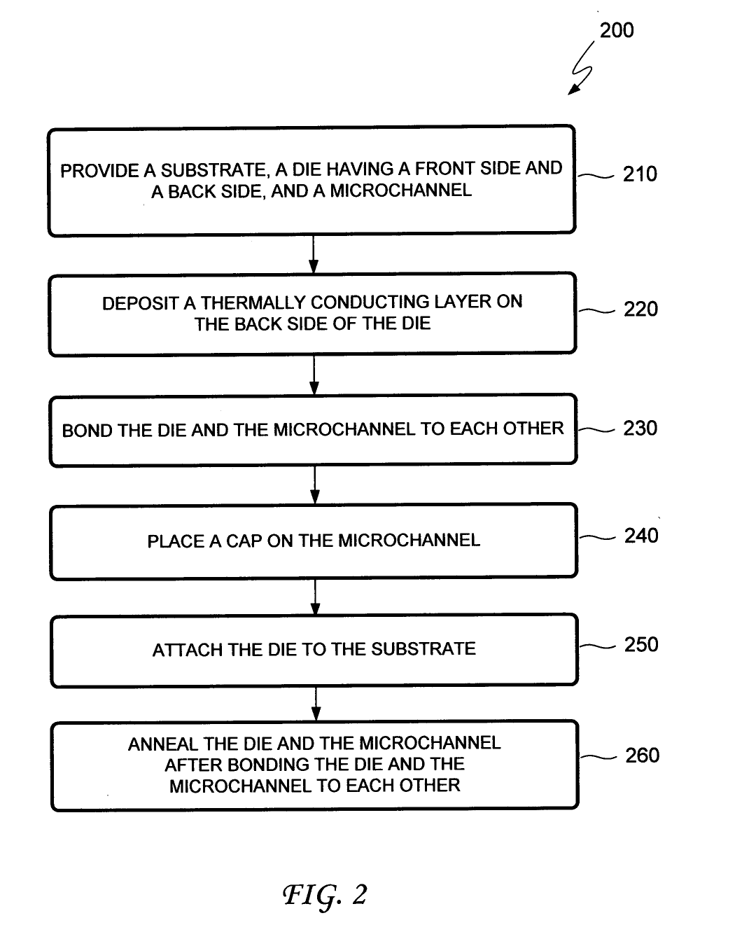

FIG. 2 is a flowchart illustrating a method 200 of manufacturing a microelectronic package according to an embodiment of the invention. A step 210 of method 200 is to provide a substrate, a die having a front side and a back side, and a microchannel. As an example, the substrate, the die, and the microchannel can be similar to, respectively, substrate 110, die 120, and microchannel 140, all of which are shown in FIG. 1. It will be understood that in accordance with techniques that are well known in the art, the substrate, the die, and the microchannel may originally be part of a wafer or the like that contains large quantities of devices that are later singulated into individual units such as die 120, substrate 110, and microchannel 140. Such singulation can occur, for example, after the die and the microchannel are bonded together as in step 230 (to be described below) or another step of method 200.

A step 220 of method 200 is to deposit a thermally conducting layer on the back side of the die. As an example, the thermally conducting layer can be similar to thermally conducting layer 130, first shown in FIG. 1. In one embodiment, step 220 comprises electroplating the thermally conducting layer onto the die. Advantageously, electroplating may provide a thin stiffening layer with a very smooth surface finish.

In the same or another embodiment, step 220 or another step can comprise depositing a barrier layer on the back side of the die prior to depositing the thermally conducting layer, depositing a second barrier layer on a first surface of the microchannel, and depositing a second thermally conducting layer over the second barrier layer. As an example, the barrier layer, the second thermally conducting layer, and the second barrier layer can be similar to, respectively, barrier layer 160, thermally conducting layer 180, and barrier layer 170, all of which are shown in FIG. 1. Similarly, the barrier layer, the second thermally conducting layer, and the second barrier layer may be deposited in a procedure similar to that used for the deposition of the thermally conducting layer.

A step 230 of method 200 is to bond the die and the microchannel to each other. In one embodiment, step 230 comprises using a surface bonding technique such as thermal compression bonding, diffusion bonding, or another substantially void- and gap-free bonding process in which the thermally conducting layer and the second thermally conducting layer are bonded together as with copper-copper bonding or the like as appropriate for the materials being used. In another embodiment, step 230 comprises using a polymer bonding technique, such as a technique involving a conductive polymer interface and a heat treatment. As an example, the polymer bonding technique may involve the use of a polymer interface material between two thermally conductive regions, such as thermally conducting layers 130 and 180.

As a particular example, two silicon wafers, both of which have a thickness of approximately 750 micrometers, may each be coated with a tantalum diffusion barrier layer of approximately 50 nanometers and a copper thermally conducting layer of approximately 300 nanometers. A successful copper-copper bonding may occur, as it has experimentally been shown to occur, between the two silicon wafers when the wafers are brought into contact at approximately 400 degrees Celsius with a down force of 4000 millibar for thirty minutes (4000 millibar is equivalent to approximately 400,000 Pascals), followed by a post-bonding anneal at approximately 400 degrees Celsius for thirty minutes in an inert nitrogen (N₂) environment.

It should be understood that in different embodiment, thickness values different from those given in the particular example above may be used. As an example, a wafer according to embodiments of the invention may have a thickness as great as approximately 750 micrometers or a thickness as small as approximately 100 micrometers.

A step 240 of method 200 is to place a cap on the microchannel. In one embodiment, step 240 comprises placing a second microchannel at a second surface of the microchannel such that the microchannel and the second microchannel are in inverted relationship with respect to each other. As an example, the second microchannel and the second surface can be similar to, respectively, microchannel 152 and surface 142, both of which are shown in FIG. 1. In a different embodiment, step 240 comprises placing a lid at the second surface of the microchannel. As an example, the lid can be similar to the lid that is represented in FIG. 1 by dotted line 151.

A step 250 of method 200 is to attach the die to the substrate. In one embodiment, step 250 comprises a C4 attach using conductive pads, solder bumps, and an underfill material in accordance with techniques known in the art. As an example, the conductive pads, the solder bumps, and the underfill material can be similar to, respectively, pads 113, solder bumps 115, and underfill material 117, all of which are shown in FIG. 1. Step 250 can be performed either before or after the performance of step 240.

A step 260 of method 200 is to anneal the die and the microchannel after bonding the die and the microchannel to each other. In one embodiment, step 260 is performed after the bonding of step 230 and before the activities of steps 240 and 250. An anneal may significantly enhance the quality of the bond between die and microchannel.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the microelectronic packages and related methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A microelectronic package comprising:
a substrate;
a die having a front side and a back side located over the substrate;
a thermally conducting layer on the back side of the die;
a microchannel above the thermally conducting layer; and
a cap on the microchannel.

2. The microelectronic package of claim 1 wherein:
the die and the microchannel are made of silicon.

3. The microelectronic package of claim 2 wherein:
the thermally conducting layer comprises copper.

4. The microelectronic package of claim 2 wherein:
the thermally conducting layer is no thicker than approximately five micrometers.

5. The microelectronic package of claim 2 further comprising:
a barrier layer between the back side of the die and the thermally conducting layer.

6. The microelectronic package of claim 5 wherein:
the thermally conducting layer comprises copper; and
the barrier layer comprises tantalum.

7. The microelectronic package of claim 5 wherein:
the microchannel has a first surface and a second surface,
the cap on the microchannel is at the second surface; and
the microchannel further comprises a second barrier layer at the first surface and a second thermally conducting layer over the second barrier layer.

8. The microelectronic package of claim 2 wherein:
the cap comprises a second microchannel.

9. A method of manufacturing a microelectronic package, the method comprising:
providing a substrate, a die having a front side and a back side, and a microchannel;
depositing a thermally conducting layer on the back side of the die;
bonding the die and the microchannel to each other;
placing a cap on the microchannel; and
attaching the die to the substrate.

10. The method of claim 9 wherein:
depositing the thermally conducting layer comprises electroplating the thermally conducting layer onto the die.

11. The method of claim 9 further comprising:
depositing a barrier layer on the back side of the die prior to depositing the thermally conducting layer;
depositing a second barrier layer on a first surface of the microchannel; and
depositing a second thermally conducting layer over the second barrier layer.

12. The method of claim 11 wherein:
providing the die comprises providing a silicon die;
providing the microchannel comprises providing a silicon microchannel;
depositing the thermally conducting layer comprises depositing a copper layer; and
depositing the barrier layer comprises depositing a tantalum layer.

13. The method of claim 9 wherein:
bonding the die and the microchannel to each other comprises using one of a surface bonding technique and a polymer bonding technique.

14. The method of claim 13 further comprising:
annealing the die and the microchannel after bonding the die and the microchannel to each other.

15. The method of claim 13 wherein:
placing the cap on the microchannel comprises one of:
placing a second microchannel at a second surface of the microchannel such that the microchannel and the second microchannel are in inverted relationship with respect to each other; and
placing a lid at the second surface of the microchannel.
